(19) United States
(12) Patent Application Publication
(10) Pub. No.: US 2024/0038613 A1
(43) Pub. Date: Feb. 1, 2024

(54) Edge Seal for Bonded Stacks of Different Size Semiconductor Devices

(71) Applicant: Avago Technologies International Sales Pte. Limited, Singapore (SG)

(72) Inventors: Sam Zhao, Irvine, CA (US); Sam Karikalan, Ladera Ranch, CA (US); Reza Sharifi, Irvine, CA (US); Mayank Mayukh, Fort Collins, CO (US); Arun Ramakrishnan, Lake Forest, CA (US); Dharmendra Saraswat, Foothill Ranch, CA (US); Liming Tsau, Irvine, CA (US)

(21) Appl. No.: 17/876,235

(22) Filed: Jul. 28, 2022

(51) Int. Cl. H01L 23/31; H01L 25/065; H01L 23/00; H01L 21/56

(52) U.S. Cl. CPC H01L 23/3135; H01L 25/0657; H01L 24/16; H01L 23/562; H01L 21/561; H01L 2224/16145

(57) ABSTRACT

Novel tools and techniques are provided for implementing edge seal for bonded stacks of different size semiconductor devices. In various embodiments, a semiconductor device is provided that includes a composite structure and a sealant material. The composite structure includes two or more semiconductor devices that form a stacked configuration with one semiconductor device being disposed on or over each of one or more other semiconductor devices (of different size compared with that of the one semiconductor device) and with interface components of the one semiconductor device being bonded with corresponding interface components to each of the one or more other semiconductor devices in the stacked configuration. The sealant material is disposed along one or more surface portions of the composite structure to cover a region including at least portions of side surfaces of the composite structure that extend to cover at least each interface portion between stacked semiconductor devices.

### COPYRIGHT STATEMENT

A portion of the disclosure of this patent document contains material that is subject to copyright protection. The copyright owner has no objection to the facsimile reproduction by anyone of the patent document or the patent disclosure as it appears in the Patent and Trademark Office patent file or records, but otherwise reserves all copyright rights whatsoever.

### FIELD

The present disclosure relates, in general, to methods, systems, and apparatuses for implementing semiconductor technology, and, more particularly, to methods, systems, and apparatuses for implementing edge seal for bonded stacks of different size semiconductor devices.

### BACKGROUND

For conventional three dimensional (“3D”) semiconductor packages, interface separation between bonded stacked dies is of top concern due to mechanical and/or electrical interconnection failure, or the like. It is difficult for conventional mechanical failure analysis methods to discover these types of interconnection failures (in the form of chip/package failure). Further, conventional 3D semiconductor packages lack suitable mechanisms for preventing die cracks and/or delamination between stacked dies that may propagate into active circuits on the stacked dies, the propagation of the die cracks and/or delamination being due to effects of wafer cutting or sawing processes.

Hence, there is a need for more robust and scalable solutions for implementing semiconductor technology, and, more particularly, to methods, systems, and apparatuses for implementing edge seal for bonded stacks of different size semiconductor devices.

### SUMMARY

The techniques of this disclosure generally relate to tools and techniques for implementing semiconductor technology, and, more particularly, to methods, systems, and apparatuses for implementing edge seal for bonded stacks of different size semiconductor devices.

In an aspect, a semiconductor device comprises a composite structure and a sealant material. The composite structure comprises a first semiconductor device and a second semiconductor device. The first semiconductor device has a top surface, a bottom surface, side surfaces extending between the top surface and the bottom surface, and one or more first interface components extending at least from one or more portions of the top surface, wherein edges between the top surface and the side surfaces define a first lateral perimeter, the first lateral perimeter defining a first area. The second semiconductor device has a top surface, a bottom surface, side surfaces extending between the top surface and the bottom surface, and one or more second interface components extending at least from one or more portions of the bottom surface, wherein edges between the bottom surface and the side surfaces define a second lateral perimeter, the second lateral perimeter defining a second area, the second area being different in size than the first area. The first and second semiconductor devices form a stacked configuration with the second semiconductor device being disposed on or over the first semiconductor device and with each of the one or more first interface components bonded with a corresponding one of the one or more second interface components. The sealant material is disposed along one or more surface portions of the composite structure to cover a region comprising at least portions of side surfaces of the composite structure that extend from below the top surface of the first semiconductor device to above the bottom surface of the second semiconductor device.

In some embodiments, the composite structure is formed on a semiconductor wafer among a plurality of composite structures that is formed in an array on the semiconductor wafer, wherein the side surfaces of the composite structure have surface features after separation from each of one or more adjacent composite structures among the plurality of composite structures that are formed on the semiconductor wafer. In some cases, the surface features comprise at least one of one or more cracks, one or more signs of chipping, one or more grooves, one or more uneven surface portions, or one or more portions characteristic of delamination of the second semiconductor device from the first semiconductor device, and/or the like. In some instances, the sealant material fills in and seals the at least one of the one or more cracks, the one or more signs of chipping, the one or more grooves, or the one or more portions characteristic of delamination, and/or the like. In some cases, the sealant material comprises at least one of adhesive, thermoset resin, thermal conductive adhesive, mold compound, epoxy, or silicon dioxide-based material, and/or the like.

According to some embodiments, the composite structure further comprises a mold region that fills in a region, other than a space occupied by the smaller of the first semiconductor device or the second semiconductor device, the region being either: (i) above the first area that extends from the top surface of the first semiconductor device to the top surface of the second semiconductor device and that extends from an interior edge of the first lateral perimeter to other interior edges of the first lateral perimeter when the second area is smaller than the first area; or (ii) below the second area that extends from the bottom surface of the first semiconductor device to the bottom surface of the second semiconductor device and that extends from an interior edge of the second lateral perimeter to other interior edges of the second lateral perimeter when the second area is larger than the first area. In some instances, the mold region comprises a first material comprising at least one of adhesive, thermoset resin, thermal conductive adhesive, mold compound, epoxy, silicon dioxide-based material, or a dielectric material, and/or the like.

In some embodiments, the composite structure further comprises at least one dummy die that is disposed within and replaces at least one portion of the mold region. In some cases, each dummy die is an inactive semiconductor structure comprising a second material that has at least one of mechanical, thermal, or electrical properties that match corresponding at least one of mechanical, thermal, or electrical properties of at least one of the first semiconductor device or the second semiconductor device, wherein a bottom surface or one or more third interface components of each dummy die is configured to facilitate bonding with the top surface or the one or more first interface components of the first semiconductor device. In some instances, the second material comprises at least one of silicon, glass, copper, aluminum, or a conductive alloy, and/or the like.

In some instances, the second area is smaller than the first area. In some cases, the first semiconductor device further comprises a plurality of protruding electrical contact terminals extending at least from one or more portions of the bottom surface of the first semiconductor device. In some instances, a top surface of the composite structure is defined by at least one of the top surface of the second semiconductor device or a top surface of the mold region. In some cases, the side surfaces of the composite structure are defined by one of: the side surfaces of the first semiconductor device and side surfaces of the mold region; or the side surfaces of the first semiconductor device, one or more of the side surfaces of the mold region, and one or more of the side surfaces of the second semiconductor device; and/or the like. In some instances, the region of the composite structure that is covered by the sealant material comprises one of: the side surfaces of the composite structure; a combination of the top surface of the composite structure and the side surfaces of the composite structure; a combination of the bottom surface of the first semiconductor device, portions of pillar portions of each of the plurality of protruding electrical contact terminals, and the side surfaces of the composite structure; a combination of the top surface of the composite structure, the bottom surface of the first semiconductor device, the portions of pillar portions of each of the plurality of protruding electrical contact terminals, and the side surfaces of the composite structure; portions of each side surface of the composite structure extending from the top surface of the second semiconductor device to a portion below the top surface of the first semiconductor device but not to the bottom surface of the first semiconductor device; or a combination of the top surface of the composite structure and the portions of each side surface of the composite structure extending from the top surface of the second semiconductor device to a portion below the top surface of the first semiconductor device but not to the bottom surface of the first semiconductor device; and/or the like.

In another aspect, a method comprises applying a mold material to a semiconductor wafer comprising a plurality of composite structures that is formed in an array. Each composite structure comprises: a first semiconductor device, the first semiconductor device having a top surface, a bottom surface, side surfaces extending between the top surface and the bottom surface, and one or more first interface components extending at least from one or more portions of the top surface, wherein edges between the top surface and the side surfaces define a first lateral perimeter, the first lateral perimeter defining a first area; and a second semiconductor device, the second semiconductor device having a top surface, a bottom surface, side surfaces extending between the top surface and the bottom surface, and one or more second interface components extending at least from one or more portions of the bottom surface, wherein edges between the bottom surface and the side surfaces define a second lateral perimeter, the second lateral perimeter defining a second area, the second area being different in size than the first area, the first and second semiconductor devices forming a stacked configuration with the second semiconductor device being disposed on or over the first semiconductor device and with each of the one or more first interface components bonded with a corresponding one of the one or more second interface components. The mold material is applied to fill, for each composite structure, a region (“mold region”), other than a space occupied by the smaller of the first semiconductor device or the second semiconductor device, the mold region being either: (i) above the first area that extends from the top surface of the first semiconductor device to the top surface of the second semiconductor device and that extends from an interior edge of the first lateral perimeter to other interior edges of the first lateral perimeter when the second area is smaller than the first area; or (ii) below the second area that extends from the bottom surface of the first semiconductor device to the bottom surface of the second semiconductor device and that extends from an interior edge of the second lateral perimeter to other interior edges of the second lateral perimeter when the second area is larger than the first area. The method further comprises cutting along paths between adjacent composite structures among the plurality of composite structures on the semiconductor; and applying a sealant material along one or more exposed surface portions of each composite structure along the cut paths to cover a region comprising at least portions of exposed side surfaces of the composite structure that extend from below the top surface of the first semiconductor device to above the bottom surface of the second semiconductor device.

In some embodiments, applying the sealant material is performed either after cutting along all paths has been completed or as cutting is being performed and before cutting along all paths has been completed.

According to some embodiments, cutting along the paths between adjacent composite structures among the plurality of composite structures on the semiconductor wafer comprises cutting completely through a height of each of the adjacent composite structures, thereby separating the adjacent composite structures. In some cases, the side surfaces of each composite structure are defined by one of: side surfaces of the mold region and the side surfaces of the larger of the first semiconductor device or the second semiconductor device; or one or more of the side surfaces of the mold region, the side surfaces of the larger of the first semiconductor device or the second semiconductor device, and one or more of the side surfaces of the smaller of the first semiconductor device or the second semiconductor device. In some instances, applying the sealant material comprises applying the sealant material to cover the side surfaces of the composite structure that are exposed by the cutting process.

In some cases, the first semiconductor device further comprises a plurality of protruding electrical contact terminals extending at least from one or more portions of the bottom surface of the first semiconductor device. In some instances, a top surface of the composite structure is defined by the top surface of the second semiconductor device and a top surface of the mold region. In some cases, applying the sealant material further comprises applying the sealant material to cover at least one of: the top surface of the composite structure; or the bottom surface of the first semiconductor device and portions of pillar portions of each of the plurality of protruding electrical contact terminals; or the like.

In some embodiments, the second area is smaller than the first area, and the composite structure further comprises at least one dummy die that is disposed within and replaces at least one portion of the mold region. In some instances, the side surfaces of each composite structure are defined by one of: the side surfaces of the first semiconductor device and side surfaces of the mold region; the side surfaces of the first semiconductor device, one or more of the side surfaces of the mold region, and one or more of the side surfaces of the second semiconductor device; the side surfaces of the first semiconductor device, one or more of the side surfaces of the mold region, and one or more side surfaces of each of one or more of the at least one dummy die; or the side surfaces of the first semiconductor device, one or more of the side surfaces of the mold region, one or more of the side surfaces of the second semiconductor device, and one or more side surfaces of each of one or more of the at least one dummy die; and/or the like. In some cases, each dummy die is an inactive semiconductor structure comprising a material that has at least one of mechanical, thermal, or electrical properties that match corresponding at least one of mechanical, thermal, or electrical properties of at least one of the first semiconductor device or the second semiconductor device. In some instances, a bottom surface or one or more third interface components of each dummy die is configured to facilitate bonding with the top surface or the one or more first interface components of the first semiconductor device.

According to some embodiments, cutting along the paths between adjacent composite structures among the plurality of composite structures on the semiconductor wafer comprises cutting partially through a height of each of the adjacent composite structures, extending from the top surface of the second semiconductor device to a portion below the top surface of the first semiconductor device of each adjacent composite structure but not to the bottom surface of the first semiconductor device. In some cases, applying the sealant material comprises applying the sealant material to cover portions of each exposed side surface of the composite structure extending from the top surface of the second semiconductor device to the portion below the top surface of the first semiconductor device but not to the bottom surface of the first semiconductor device. In some instances, the method further comprises: cutting completely through the height of each of the adjacent composite structures including through the applied sealant material, thereby separating the adjacent composite structures.

In some cases, the one or more exposed surface portions of each composite structure have surface features resulting from the cutting process. In some instances, the surface features comprise at least one of one or more cracks, one or more signs of chipping, one or more grooves, one or more uneven surface portions, or one or more portions characteristic of delamination of the second semiconductor device from the first semiconductor device, and/or the like. In some cases, the sealant material fills in and seals the at least one of the one or more cracks, the one or more signs of chipping, the one or more grooves, or the one or more portions characteristic of delamination, and/or the like.

In yet another aspect, a semiconductor device comprises: a composite structure and a sealant material. The composite structure comprises: a first semiconductor device; a second semiconductor device that is smaller than the first semiconductor device and that is disposed on or over and bonded to the first semiconductor device; at least one dummy die that is smaller than the first semiconductor device and that is disposed on or over and bonded to the first semiconductor device; and a mold region that fills in a first region, other than a space occupied by the second semiconductor device and each of the at least one dummy die, that extends from a top surface of the first semiconductor device to a top surface of the second semiconductor device or a top surface of the at least one dummy die and that extends from an interior edge of a lateral perimeter of the first semiconductor device to other interior edges of the lateral perimeter of the first semiconductor device. The sealant material is disposed along one or more surface portions of the composite structure to cover a second region comprising at least portions of side surfaces of the composite structure that extend from below the top surface of the first semiconductor device to above a bottom surface of the second semiconductor device.

In some instances, the first semiconductor device further comprises a plurality of protruding electrical contact terminals extending at least from one or more portions of a bottom surface of the first semiconductor device. In some cases, a top surface of the composite structure is defined by at least one of the top surface of the second semiconductor device, a top surface of the at least one dummy die, or a top surface of the mold region. In some instances, side surfaces of the composite structure are defined by one of: side surfaces of the first semiconductor device and side surfaces of the mold region; the side surfaces of the first semiconductor device, one or more of the side surfaces of the mold region, and one or more side surfaces of the second semiconductor device; the side surfaces of the first semiconductor device, one or more of the side surfaces of the mold region, and one or more side surfaces of each of one or more of the at least one dummy die; or the side surfaces of the first semiconductor device, one or more of the side surfaces of the mold region, one or more side surfaces of the second semiconductor device, and one or more side surfaces of each of one or more of the at least one dummy die; and/or the like. In some cases, the second region of the composite structure that is covered by the sealant material comprises one of: the side surfaces of the composite structure; a combination of the top surface of the composite structure and the side surfaces of the composite structure; a combination of the bottom surface of the first semiconductor device, portions of pillar portions of each of the plurality of protruding electrical contact terminals, and the side surfaces of the composite structure; a combination of the top surface of the composite structure, the bottom surface of the first semiconductor device, the portions of pillar portions of each of the plurality of protruding electrical contact terminals, and the side surfaces of the composite structure; portions of each side surface of the composite structure extending from the top surface of the second semiconductor device to a portion below the top surface of the first semiconductor device but not to the bottom surface of the first semiconductor device; or a combination of the top surface of the composite structure and the portions of each side surface of the composite structure extending from the top surface of the second semiconductor device to a portion below the top surface of the first semiconductor device but not to the bottom surface of the first semiconductor device; and/or the like.

Various modifications and additions can be made to the embodiments discussed without departing from the scope of the invention. For example, while the embodiments described above refer to particular features, the scope of this invention also includes embodiments having different combination of features and embodiments that do not include all of the above-described features.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF THE DRAWINGS

A further understanding of the nature and advantages of particular embodiments may be realized by reference to the remaining portions of the specification and the drawings, in which like reference numerals are used to refer to similar components. In some instances, a sub-label is associated with a reference numeral to denote one of multiple similar components. When reference is made to a reference numeral without specification to an existing sub-label, it is intended to refer to all such multiple similar components.

FIG. 1A-1X are schematic diagrams illustrating sectional or cutaway elevation views of various non-limiting sets of examples of composite structures, in the form of bonded stacks of different size semiconductor devices, with edge seals, in accordance with various embodiments.

FIGS. 2A-2H are schematic diagrams illustrating plan views of various non-limiting sets of examples of composite structures, in the form of bonded stacks of different size semiconductor devices, with edge seals, in accordance with various embodiments.

FIG. 3A-3F are schematic diagrams illustrating sectional or cutaway elevation views of a non-limiting set of examples of forming composite structures, in the form of bonded stacks of different size semiconductor devices, with edge seals during implementation of edge seal for bonded stacks of different size semiconductor devices, in accordance with various embodiments.

FIGS. 4A-4F are schematic diagrams illustrating sectional or cutaway elevation views of another non-limiting set of examples of forming composite structures, in the form of bonded stacks of different size semiconductor devices, with edge seals during implementation of edge seal for bonded stacks of different size semiconductor devices, in accordance with various embodiments.

FIGS. 5A-5C are flow diagrams illustrating a method for implementing edge seal for bonded stacks of different size semiconductor devices, in accordance with various embodiments.

### DETAILED DESCRIPTION

### Overview

Various embodiments provide tools and techniques for implementing semiconductor technology, and, more particularly, to methods, systems, and apparatuses for implementing edge seal for bonded stacks of different size semiconductor devices.

In various embodiments, a semiconductor device is provided that comprises a composite structure and a sealant material. The composite structure comprises a first semiconductor device and a second semiconductor device. The first semiconductor device has a top surface, a bottom surface, side surfaces extending between the top surface and the bottom surface, and one or more first interface components extending at least from one or more portions of the top surface, wherein edges between the top surface and the side surfaces define a first lateral perimeter, the first lateral perimeter defining a first area. The second semiconductor device has a top surface, a bottom surface, side surfaces extending between the top surface and the bottom surface, and one or more second interface components extending at least from one or more portions of the bottom surface, wherein edges between the bottom surface and the side surfaces define a second lateral perimeter, the second lateral perimeter defining a second area, the second area being different in size than the first area. The first and second semiconductor devices form a stacked configuration with the second semiconductor device being disposed on or over the first semiconductor device and with each of the one or more first interface components bonded with a corresponding one of the one or more second interface components. The sealant material is disposed along one or more surface portions of the composite structure to cover a region comprising at least portions of side surfaces of the composite structure that extend from below the top surface of the first semiconductor device to above the bottom surface of the second semiconductor device (in some cases, to cover at least each interface portion between stacked semiconductor devices).

In the various aspects described herein, edge seal for bonded stacks of different size semiconductor devices is implemented. The edge seal provides additional bonding force for the bonded die stacks as well as protecting the bonding interface from stresses and environmental corrosion, while also preventing die or device separation between at least two stacked dies both during the manufacturing process and during use by customers or end users. Edges or sides of the stacked dies may be one of fully aligned (i.e., with all die edges of one or more dies being aligned with those of another die; or with 100% common die edges), partially aligned (i.e., with one or more edges of each of one or more dies being aligned with those of another die), or not aligned (i.e., with none of the edges of any dies being aligned with those of another die), or the like.

These and other aspects of the substrate, semiconductor package, and method for implementing edge seal for bonded stacks of different size semiconductor devices are described in greater detail with respect to the figures.

The following detailed description illustrates a few embodiments in further detail to enable one of skill in the art to practice such embodiments. The described examples are provided for illustrative purposes and are not intended to limit the scope of the invention.

In the following description, for the purposes of explanation, numerous details are set forth in order to provide a thorough understanding of the described embodiments. It will be apparent to one skilled in the art, however, that other embodiments of the present invention may be practiced without some of these details. In other instances, some structures and devices are shown in block diagram form. Several embodiments are described herein, and while various features are ascribed to different embodiments, it should be appreciated that the features described with respect to one embodiment may be incorporated with other embodiments as well. By the same token, however, no single feature or features of any described embodiment should be considered essential to every embodiment of the invention, as other embodiments of the invention may omit such features.

Unless otherwise indicated, all numbers used herein to express quantities, dimensions, and so forth used should be understood as being modified in all instances by the term “about.” In this application, the use of the singular includes the plural unless specifically stated otherwise, and use of the terms “and” and “or” means “and/or” unless otherwise indicated. Moreover, the use of the term “including,” as well as other forms, such as “includes” and “included,” should be considered non-exclusive. Also, terms such as “element” or “component” encompass both elements and components comprising one unit and elements and components that comprise more than one unit, unless specifically stated otherwise.

Some Embodiments

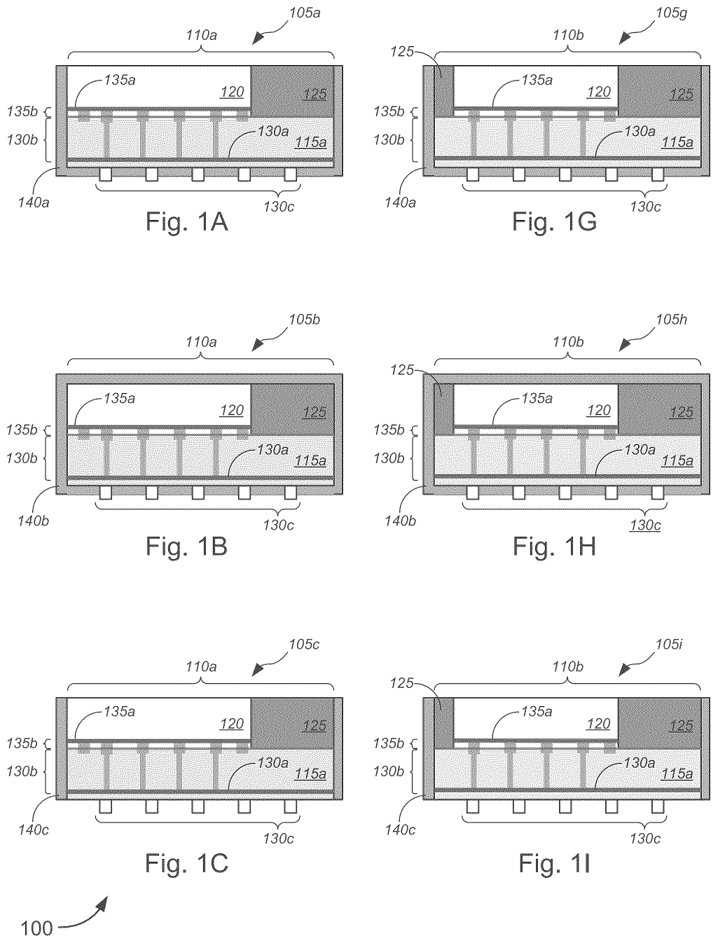

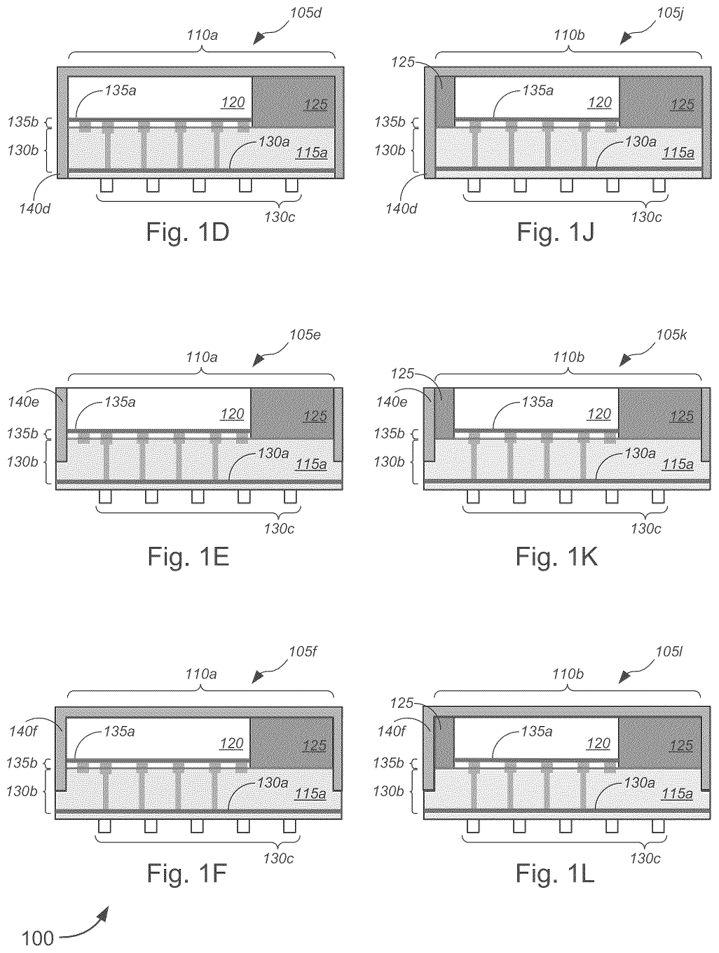

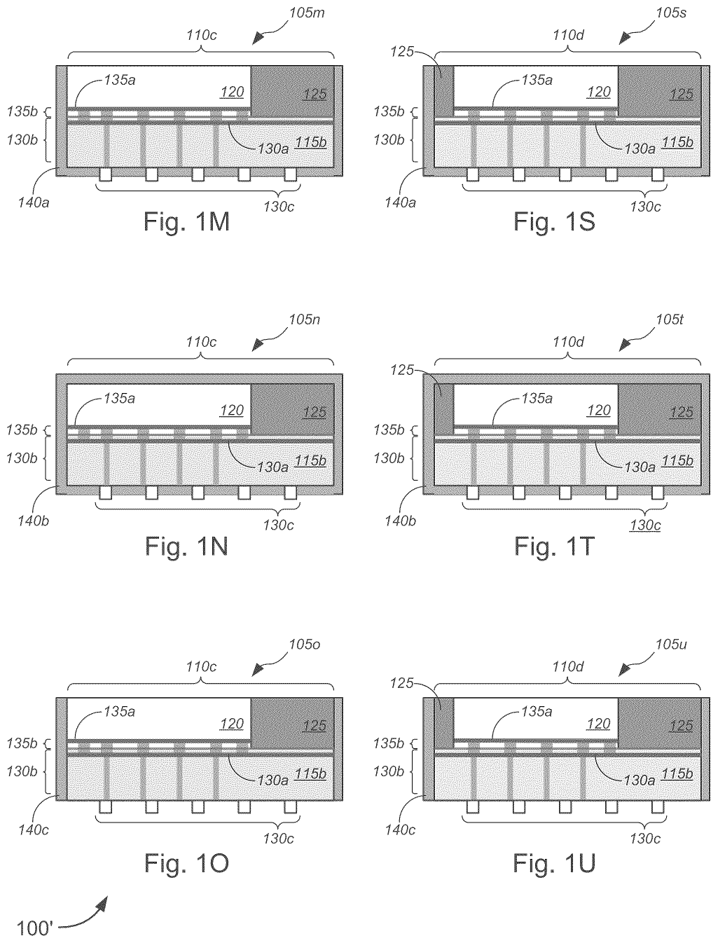

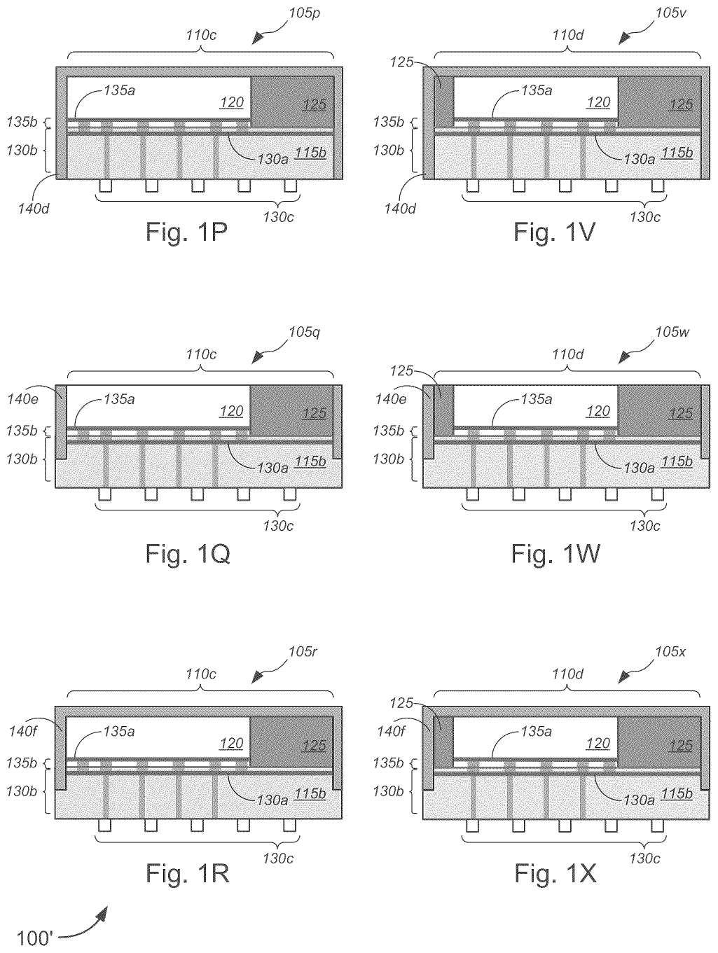

We now turn to the embodiments as illustrated by the drawings. FIGS. 1-5 illustrate some of the features of the method, system, and apparatus for implementing semiconductor technology, and, more particularly, to methods, systems, and apparatuses for implementing edge seal for bonded stacks of different size semiconductor devices, as referred to above. The methods, systems, and apparatuses illustrated by FIGS. 1-5 refer to examples of different embodiments that include various components and steps, which can be considered alternatives or which can be used in conjunction with one another in the various embodiments. The description of the illustrated methods, systems, and apparatuses shown in FIGS. 1-5 is provided for purposes of illustration and should not be considered to limit the scope of the different embodiments.

When an element is referred to herein as being “connected” (or “interconnected”) or “coupled” to another element, it is to be understood that the elements can be directly connected to the other element, or have intervening elements present between the elements. In contrast, when an element is referred to as being “directly connected” or “directly coupled” to another element, it should be understood that no intervening elements are present in the “direct” connection between the elements. However, the existence of a direct connection does not exclude other connections, in which intervening elements may be present.

Similarly, when an element is referred to herein as being “bonded” to another element, it is to be understood that the elements can be directly bonded to the other element (without any intervening elements) or have intervening elements present between the bonded elements. In contrast, when an element is referred to as being “directly bonded” to another element, it should be understood that no intervening elements are present in the “direct” bond between the elements. However, direct bonding does not exclude other forms of bonding, in which intervening elements may be present.

Likewise, when an element is a layer, it is to be understood that such element can be a single layer or a series of multiple layers. When described in relation to other layers among a plurality of layers, such element can be said to be directly connected to another layer among the plurality of layers or have intervening elements or layers present between the element and the another layer. In contrast, when the element is referred to as being “directly connected” or “directly coupled” to another layer, it should be understood that no intervening elements or layers are present in the “direct” connection between the element and the another layer. However, the existence of a direct connection does not exclude other connections, in which intervening elements or layers may be present.

When an element is described as being “on” or disposed “on” another element, it is to be understood that such element can be said to be directly on (or disposed on) the another element or have intervening elements or layers present between the element and the another element. In contrast, when the element is referred to as being “directly on” or “directly disposed on” another element, it should be understood that no intervening elements or layers are present in the “direct” connection between the element and the another element. However, the existence of a direct connection does not exclude other connections, in which intervening elements or layers may be present.

Herein, the use of the phrase “at least one of” together with “or” should be understood to mean “and/or.” For example, “at least one of A, B, or C” should be understood to mean “A, B, and/or C” or “only A, only B, or both A and B.” This applies to any number of items listed after “at least one of” and is not limited to the three items as listed in the preceding example.

With reference to the figures, FIG. 1A-1X (collectively, “FIG. 1”) are schematic diagrams illustrating sectional or cutaway elevation views of various non-limiting sets of examples 100 and 100′ of composite structures, in the form of bonded stacks of different size semiconductor devices, with edge seals, in accordance with various embodiments. FIGS. 1A-1L depict the set of examples 100 in which semiconductor devices 105a-1051 comprise composite structures 110a and 110b in which the active circuits of first and second semiconductor devices are on or near the bottom surfaces (i.e., within the bottom half or bottom quarter) of each of said first and second semiconductor devices, while FIGS. 1M-1X depict the set of examples 100′ in which semiconductor devices 105m-105x comprise composite structures 110c and 110d in which the active circuits of the first semiconductor device are on or near the top surfaces (i.e., within the top half or top quarter) of said first semiconductor device and the active circuits of the second semiconductor devices are on or near the bottom surfaces (i.e., within the bottom half or bottom quarter) of said second semiconductor device (i.e., with the active circuits of the two semiconductor devices facing each other).

Herein, the term “active circuit” or “active circuits” refers to a circuit(s), functional circuit(s), and/or integrated circuit(s) (“IC(s)”) disposed on the first or second semiconductor device that performs one or more functions of the first or second semiconductor device, respectively. During fabrication when the composite structures 110 are formed as an interconnected array on a semiconductor wafer—with the first semiconductor devices 115 having been formed on the semiconductor wafer as an interconnected array with each singulated second semiconductor devices 120 (i.e., second semiconductor devices 120 that have been cut into individual devices from the wafer on which they were formed as an interconnected array) being attached (directly or indirectly) to or on each of the (interconnected) first semiconductor devices 115—prior to being separated by dicing or other cutting process(es) (also known as “wafer singulation process(es)” or the like), the first and second semiconductor devices 115 and 120 are in the form of semiconductor dies for forming the particular components making up their respective active circuits, interface components, monolithic or multi-component structures, other sub-components, and/or intervening layers or interconnects between such components or sub-components, or the like, and thus the first and second semiconductor devices 115 and 120 may also be referred to as “dies” or “semiconductor dies,” or the like. Herein also, the term “edge seal” or “edge seals” refers to sealant material after it has been applied to one or more edges or sides of the composite structures 110. Herein, “bonded” refers to “directly or indirectly bonded.” For example, the second semiconductor device (or its bottom surface or the one or more second interface components) is (are) directly or indirectly bonded to the first semiconductor device (or its top surface or the one or more first interface components). Likewise, each dummy die (or its bottom surface or the one or more third interface components) is (are) directly or indirectly bonded to the first semiconductor device (or its top surface or the one or more first interface components). For example, in the case of direct bonding, conductive material of the interconnecting components (e.g., copper, aluminum, conductive alloy, or the like) of one device or die is bonded directly with corresponding conductive material of the interconnecting components (e.g., copper, aluminum, conductive alloy, or the like) of another device or die, or the like. In the case of indirect bonding, bonding agents (e.g., solder material, molten metals, molten metal alloys, conductive adhesives, or other adhesives, etc.) may be used to facilitate bonding between the interconnecting components of the two bonded devices, or the like. Although FIGS. 1-4 depict the various components in direct contact with each other, the various embodiments are not so limited, and any number of suitable intervening components, layers, and/or interfaces (not shown), or the like, may be used.

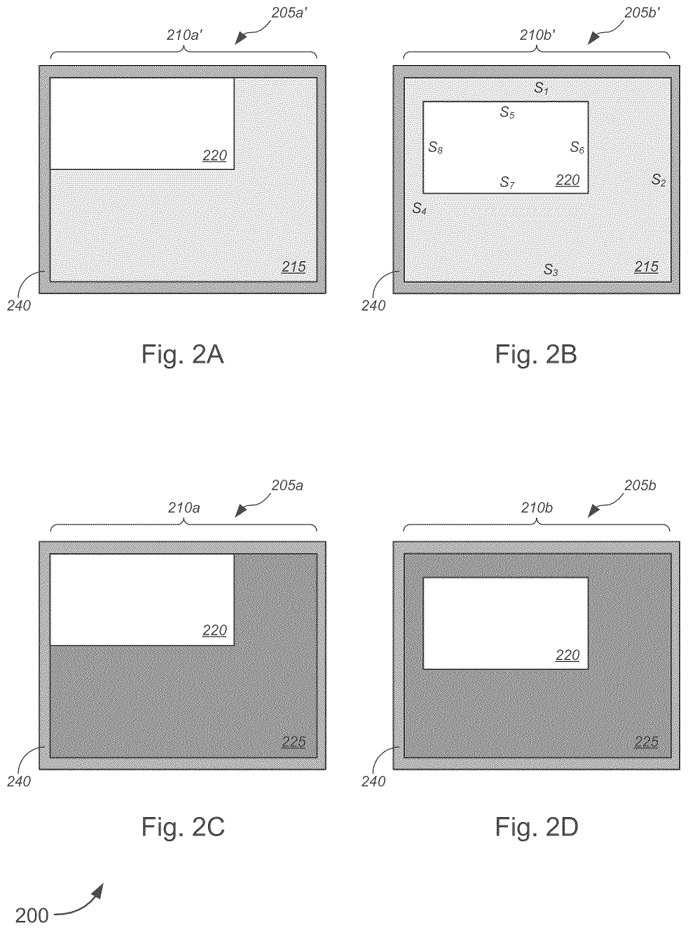

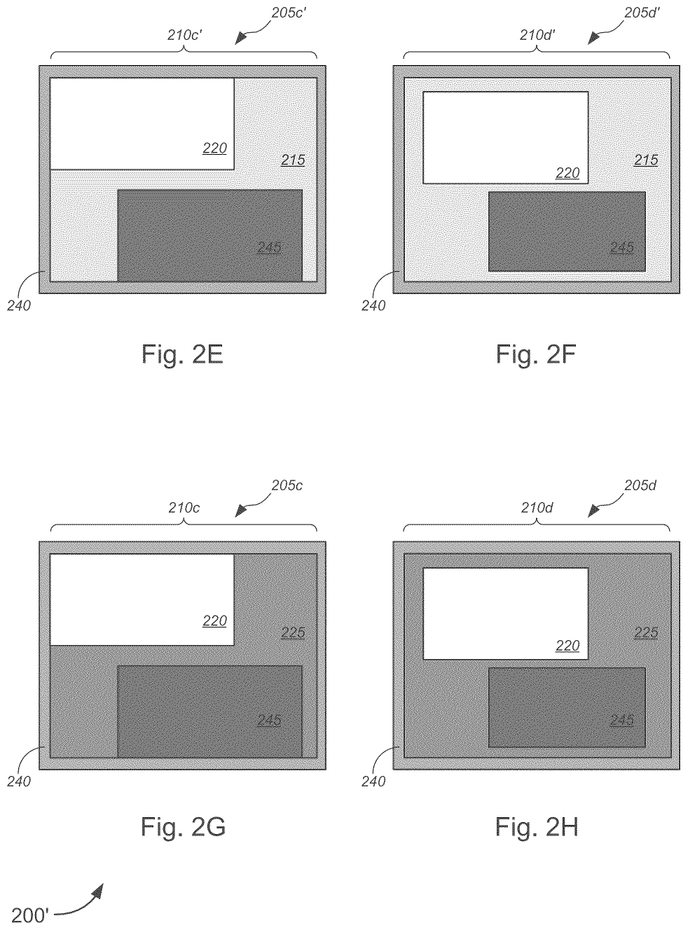

Herein, “composite structure” may refer to a configuration in which two or more semiconductor devices are stacked one on top of another (either directly or indirectly; in some cases, with at least one side edge of one aligned with corresponding at least one side edge of another, while in other cases, with side edges of each off-set from corresponding side edges of a vertically adjacent one, as shown and described below with respect to FIG. 2, or the like), in some cases, with two vertically adjacent semiconductor devices being bonded together (either directly or indirectly), and, in some cases, including the mold region, the sealant material, and/or the at least one dummy dies, each as described in detail below (and as shown in the figures). Although FIGS. 1-4 depict composite structures having one semiconductor device (or one semiconductor device and one dummy die) in stacked or bonded stack configuration with one other semiconductor device, the various embodiments are not so limited, and the composite structures may include any suitable number of semiconductor devices, each set stacked (and bonded) on top of another, with mold material filling in the spaces left by smaller sized devices that are in stacked configuration with a largest device. In some cases, although the largest size device may be at the bottom, with smaller devices stacked on top, other cases may include the largest size device stacked on top of a smaller sized device(s). In some cases, same sized devices may be stacked on top of each other, or with intervening smaller (or larger) devices stacked in between, or the like. Herein, the terms “top,” “bottom,” “sides,” and/or similar terms are relative in nature and modify the objects whose relative orientations are being described. For example, when describing the top surfaces and the bottom surfaces of two vertically stacked semiconductor devices (forming a composite structure, as described above), “top surface” and “bottom surface” refers to the relative orientations such that the top surface of the bottom semiconductor device is connected (either directly or indirectly) with the bottom surface of the top semiconductor device, while the top surface of the top semiconductor device and the bottom surface of the bottom semiconductor device in the stacked arrangement are at opposite ends of the such a composite structure, and/or the like. It is to be understood that these relative directional or orientational terms may change should the frame of reference for describing the relative objects (e.g., the components of the composite structure in the example above) were to change. Herein, “interface components” may include, without limitation, at least one of ball grid arrays, contact pads (with or without solder balls or solder material), protruding electrical contact terminals (not unlike protruding electrical contact terminals 130c, or the like; e.g., posts, bumps, etc.), and/or any other suitable structure that connects vertically adjacent semiconductor devices (whether directly or indirectly), or the like.

FIGS. 1A-1F depict a non-limiting set of examples [also referred to as “edge aligned” embodiments] in which at least one edge or side of the second semiconductor 120 is aligned with an edge or side of the first semiconductor device 115a when the first and second semiconductor devices of the composite structure 110a are in the bonded stack configuration, as described in detail below. FIGS. 1G-1L depict a non-limiting set of examples [also referred to as “edge not aligned” embodiments] in which none of the edges or sides of the second semiconductor 120 are aligned with any edge or side of the first semiconductor device 115a when the first and second semiconductor devices of the composite structure 110b are in the bonded stack configuration, as described in detail below. Similarly, FIGS. 1M-1R depict a non-limiting set of examples [also referred to as “edge aligned” embodiments] in which at least one edge or side of the second semiconductor 120 is aligned with an edge or side of the first semiconductor device 115b when the first and second semiconductor devices of the composite structure 110c are in the bonded stack configuration, as described in detail below. FIGS. 1S-1X depict a non-limiting set of examples [also referred to as “edge not aligned” embodiments] in which none of the edges or sides of the second semiconductor 120 are aligned with any edge or side of the first semiconductor device 115b when the first and second semiconductor devices of the composite structure 110d are in the bonded stack configuration, as described in detail below.

In the non-limiting examples of FIGS. 1A-1X, the semiconductor devices 105a-105x (collectively, “semiconductor devices 105” or the like) each includes, without limitation, a composite structure 110a, 110b, 110c, or 110d (collectively, “composite structure 110” or the like; as shown and described above and below), a first semiconductor device 115a or 115b (as shown and described above and below), a second semiconductor device 120, a mold region 125, first active circuit 130a, associated one or more first interface components 130b, and a plurality of first protruding electrical contact terminals 130c (including, but not limited to, conductive posts or bumps, or the like) for the first semiconductor device 115a or 115b, second active circuit 135a and associated one or more second interface components 135b for the second semiconductor device 120, and sealant material 140a, 140b, 140c, 140d, 140e, or 140f (collectively, “sealant material 140” or “edge seal” or the like; as described below).

In some embodiments, the first semiconductor device 115a or 115b includes, but is not limited to, a top surface, a bottom surface, side surfaces extending between the top surface and the bottom surface, and one or more first interface components 130b extending at least from one or more portions of the top surface. In some cases, edges between the top surface and the side surfaces define a first lateral perimeter, the first lateral perimeter defining a first area. For example, as shown, e.g., with reference to FIG. 2B, side surfaces S₁, S₂, S₃, and S₄ (at least at the edges between the top surface and the side surfaces themselves) form a first lateral perimeter (P₁=S₁+S₂+S₃+S₄) around first semiconductor device 215 (corresponding to first semiconductor device 115a or 115b, or the like). The first lateral perimeter (or the side surfaces S₁, S₂, S₃, and S₄ (at least at the edges between the top surface and the side surfaces themselves) define the first area (A₁=S₁×S₂ or A₁=S₃×S₄, or the like, in the case that the first semiconductor device has a shape of a rectangular prism, although not limited to such shape).

Similarly, the second semiconductor device 120 includes, but is not limited to, a top surface, a bottom surface, side surfaces extending between the top surface and the bottom surface, and one or more second interface components 135b extending at least from one or more portions of the bottom surface. In some instances, the one or more first interface components 130b also extend from below the top surface of the first semiconductor device 115a or 115b, while the one or more second interface components 135b also extend from above the bottom surface of the second semiconductor device 120, as shown, e.g., in FIG. 1 in which the one or more first interface components 130b extending from below the top surface of the first semiconductor device 115a or 115b couple (directly or indirectly) with corresponding one or more second interface components 135b extending from above the bottom surface of the second semiconductor device 120. In a similar manner, the protruding electrical contact terminals 130c may extend from above the bottom surface of the first semiconductor device 115a or 115b. In some cases, edges between the bottom surface and the side surfaces define a second lateral perimeter, the second lateral perimeter defining a second area, the second area being different in size than the first area. In other words, the second semiconductor device 125 is different in size (e.g., smaller or larger) than the first semiconductor device 115a or 115b at least in terms of their lateral dimensions, or the like. Similar to the first lateral perimeter and first area described above, as shown, e.g., with reference to FIG. 2B, side surfaces S₅, S₆, S₇, and S₈ (at least at the edges between the bottom surface and the side surfaces themselves) form a second lateral perimeter (P₂=S₅+S₆+S₇+S₈) around second semiconductor device 220 (corresponding to second semiconductor device 120, or the like). The second lateral perimeter (or the side surfaces S₅, S₆, S₇, and S₈ (at least at the edges between the bottom surface and the side surfaces themselves) define the second area (A₂=S₅×S₆ or A₂=S₇×S₈, or the like, in the case that the second semiconductor device has a shape of a rectangular prism, although not limited to such shape). In some instances, the first and second semiconductor devices form a stacked configuration or bonded stack configuration, with the second semiconductor device being disposed on or over the first semiconductor device and with each of the one or more first interface components bonded with a corresponding one of the one or more second interface components.

According to some embodiments, the mold material is applied to fill, for each composite structure, a region (“mold region 125”), other than a space occupied by the second semiconductor device, above the first area that extends from the top surface of the first semiconductor device to a top surface of the second semiconductor device and that extends from an interior edge of the first lateral perimeter to other interior edges of the first lateral perimeter. In some cases, although not shown, the mold region 125 may extend above the top surface of the second semiconductor device 120 (thereby resulting in the top surface of the mold region 125 defining the top surface of the composite structure 110) or below the top surface of the second semiconductor device 120 (thereby resulting in top surfaces of both the second semiconductor device 120 and the mold region 125 defining stepped top surfaces of the composite structure 110). In the case of the stepped top surfaces of the composite structure, for semiconductor devices 105 that have sealant material applied to cover the top surface(s) of the composite material, such embodiments may include either a flat-topped resultant top seal edge (in which the sealant material is thicker between its top surface and the top surface of the mold region 125 and thinner between its top surface and the top surface of the second semiconductor device 120), or a stepped top seal edge that follows the contours of the stepped top surfaces of the composite structure, or the like. In some instances, the mold region comprises a first material including, without limitation, at least one of adhesive, thermoset resin, thermal conductive adhesive, mold compound, epoxy, silicon dioxide-based material, or a dielectric material, and/or the like.

According to some embodiments, the composite structure 110 is formed on a semiconductor wafer among a plurality of composite structures that is formed in an array on the semiconductor wafer. The side surfaces of the composite structure have surface features resulting from a cutting device (including, but not limited to, a mechanical wafer saw, a laser-based wafer grooving device, a plasma dry etch wafer singulation device, or a combination of a laser wafer grooving device and a mechanical wafer saw, or the like) used to separate the composite structure from each of one or more adjacent composite structures among the plurality of composite structures that are formed on the semiconductor wafer. In some cases, the surface features include, but are not limited to, at least one of one or more cracks, one or more signs of chipping, one or more grooves, one or more uneven surface portions, or one or more portions characteristic of delamination of the second semiconductor device from the first semiconductor device (e.g., signs denoting separation of at least portions of the second semiconductor device from at least portions of the first semiconductor device, or vice versa, or the like), and/or the like. In some instances, the sealant material 140 fills in and seals the at least one of the one or more cracks, the one or more signs of chipping, the one or more grooves, or the one or more portions characteristic of delamination, and/or the like. In some cases, the sealant material 140 includes, without limitation, at least one of adhesive, thermoset resin, thermal conductive adhesive, mold compound, epoxy, or silicon dioxide-based material, and/or the like.

As shown in the non-limiting examples of semiconductor devices 105a, 105g, 105m, and 105s of FIGS. 1A, 1G, 1M, and 1S, respectively, the sealant material or edge seal 140a is applied on five sides of the composite structure 110a, 110b, 110c, and 110d, respectively, namely, a combination of the bottom surface of the first semiconductor device, portions of pillar portions of each of the plurality of protruding electrical contact terminals, and the side surfaces of the composite structure. As shown in the non-limiting examples of semiconductor devices 105b, 105h, 105n, and 105t of FIGS. 1B, 1H, 1N, and 1T, respectively, the sealant material or edge seal 140b is applied on six sides of the composite structure 110a, 110b, 110c, and 110d, respectively, namely, a combination of the top surface of the composite structure, the bottom surface of the first semiconductor device, the portions of pillar portions of each of the plurality of protruding electrical contact terminals, and the side surfaces of the composite structure. As shown in the non-limiting examples of semiconductor devices 105c, 105i, 105o, and 105u of FIGS. 1C, 1I, 1O, and 1U, respectively, the sealant material or edge seal 140c is applied on four sides of the composite structure 110a, 110b, 110c, and 110d, respectively, namely, the side surfaces of the composite structure. As shown in the non-limiting examples of semiconductor devices 105d, 105j, 105p, and 105v of FIGS. 1D, 1J, 1P, and iv, respectively, the sealant material or edge seal 140d is applied on five sides of the composite structure 110a, 110b, 110c, and 110d, respectively, namely, a combination of the top surface of the composite structure and the side surfaces of the composite structure. As shown in the non-limiting examples of semiconductor devices 105e, 105k, 105q, and 105w of FIGS. 1E, 1K, 1Q, and 1W, respectively, the sealant material or edge seal 140e is applied on four partial sides of the composite structure 110a, 110b, 110c, and 110d, respectively, namely, portions of each side surface of the composite structure extending from the top surface of the second semiconductor device to a portion below the top surface of the first semiconductor device but not to the bottom surface of the first semiconductor device. As shown in the non-limiting examples of semiconductor devices 105f, 1051, 105r, and 105x of FIGS. 1F, 1L, 1R, and 1X, the sealant material or edge seal 140f is applied on five (partial) sides of the composite structure 110a, 110b, 110c, and 110d, respectively, namely, a combination of the top surface of the composite structure and the portions of each side surface of the composite structure extending from the top surface of the second semiconductor device to a portion below the top surface of the first semiconductor device but not to the bottom surface of the first semiconductor device.

These and other functions of the sets of examples 100 and 100′ (and their components) are described in greater detail below with respect to FIGS. 2-5.

FIGS. 2A-2H (collectively, “FIG. 2”) are schematic diagrams illustrating plan views of various non-limiting sets of examples 200 and 200′ of composite structures, in the form of bonded stacks of different size semiconductor devices, with edge seals, in accordance with various embodiments. FIGS. 2A-2D depict the set of examples 200 in which semiconductor devices 205a and 205b comprise composite structures 210a and 210b, respectively, that include the first and second semiconductor devices 215 and 220 in a bonded stack configuration, while FIGS. 2E-2H depict the set of examples 200′ in which semiconductor devices 205c and 205d comprise composite structures 210c and 210d, respectively, that include the second semiconductor device 220 and at least one dummy die 245 in a bonded stack configuration with the first semiconductor device 215.

FIGS. 2A, 2B, 2E, and 2F depict the respective semiconductor devices 205a′, 205b′, 205c′, and 205d′ without mold region 225, for simplicity of illustration, to show the positional relationship(s) between the first semiconductor device 215 and the second semiconductor device 215 (as shown, e.g., in FIGS. 2A and 2B) or between the first semiconductor device 215 and each of the second semiconductor device 215 and the at least one dummy die 245 (as shown, e.g., in FIGS. 2E and 2F). FIGS. 2C, 2D, 2G, and 2H depict the corresponding set of semiconductor devices 205a, 205b, 205c, and 205d with mold region 225 bordering and in direct or indirect contact with one or more side surfaces of the second semiconductor device (as shown, e.g., in FIGS. 2C and 2D) or bordering and in direct or indirect contact with each of one or more side surfaces of the second semiconductor device 215 and one or more side surfaces of the at least one dummy die 245 (as shown, e.g., in FIGS. 2G and 2H). Although sealant material 240 is shown applied around the side portions of the composite structures 210, the various embodiments are not so limited, and sealant material may be applied to any combination of the side surfaces (or portions of the side surfaces), the top surface, or the bottom surface of the composite structures, as shown, e.g., in FIGS. 1A-1X, or the like.

In some instances, each dummy die 245 is an inactive semiconductor structure comprising a material that has at least one of mechanical, thermal, or electrical properties that match corresponding at least one of mechanical, thermal, or electrical properties of at least one of the first semiconductor device or the second semiconductor device, thereby protecting the semiconductor device 205 from effects of thermal and/or mechanical stresses, electromagnetic interference, heat dissipation, and/or other effects, or the like. In some instances, a bottom surface or one or more third interface components of each dummy die is configured to facilitate bonding with the top surface or the one or more first interface components of the first semiconductor device. Herein, according to some embodiments, “configured to facilitate bonding” may include, without limitation, conditioning the bottom surface of each dummy die (or a connecting surface of each third interface component) using at least one of thermal conditioning, chemical conditioning, or physical conditioning, applying an adhesive material on at least the bottom surface of each dummy die (or the connecting surface of each third interface component), and/or the like. In some cases, a top surface of the composite structure is defined by at least one of the top surface of the second semiconductor device, the top surface of each dummy die (if present), or a top surface of the mold region.

In some embodiments, the side surfaces of each composite structure 210a, 210b, 210c, and 210d are defined by one of: the side surfaces of the first semiconductor device 215 and side surfaces of the mold region 225 (as shown, e.g., in FIGS. 2B/2D or 2F/2H, or the like); the side surfaces of the first semiconductor device 215, one or more of the side surfaces of the mold region 225, and one or more of the side surfaces of the second semiconductor device 220 (as shown, e.g., in FIG. 2A/2C, or the like); the side surfaces of the first semiconductor device 215, one or more of the side surfaces of the mold region 225, and one or more side surfaces of each of one or more of the at least one dummy die 245 (not shown); or the side surfaces of the first semiconductor device 215, one or more of the side surfaces of the mold region 225, one or more of the side surfaces of the second semiconductor device 220, and one or more side surfaces of each of one or more of the at least one dummy die 245 (as shown, e.g., in FIG. 2E/2G, or the like); and/or the like.

Although FIG. 2 depicts particular sizes and configurations of the bonded stack configuration, the various embodiments are not so limited, and each of the second semiconductor device 220 and the at least one dummy die 245 can be of different sizes relative to each other and relative to the first semiconductor device 215, and each of the second semiconductor device 220 and the at least one dummy die 245 can be positioned with one, two, or three edges or sides aligned relative to corresponding edges or sides of the first semiconductor device 215. Although one second semiconductor device 220 and one dummy die 245 are shown in FIG. 2, the various embodiments are not so limited, and any suitable number of second semiconductor devices 220 and dummy dies 245 may be used in the bonded stack configuration with the first semiconductor device 215.

These and other functions of the sets of examples 200 and 200′ (and their components) are described in greater detail herein with respect to FIGS. 1 and 3-5.

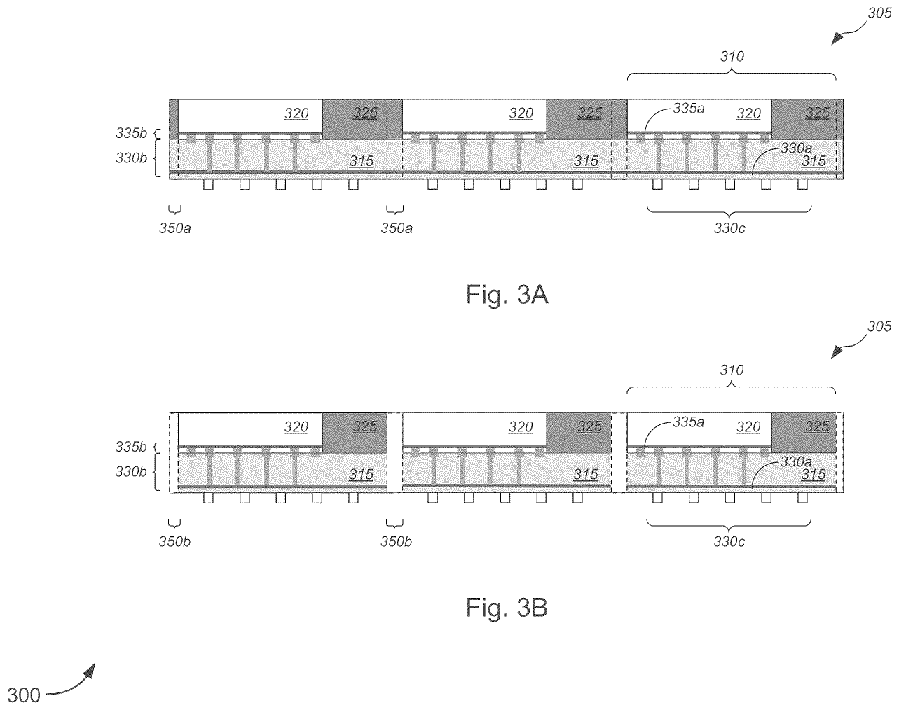

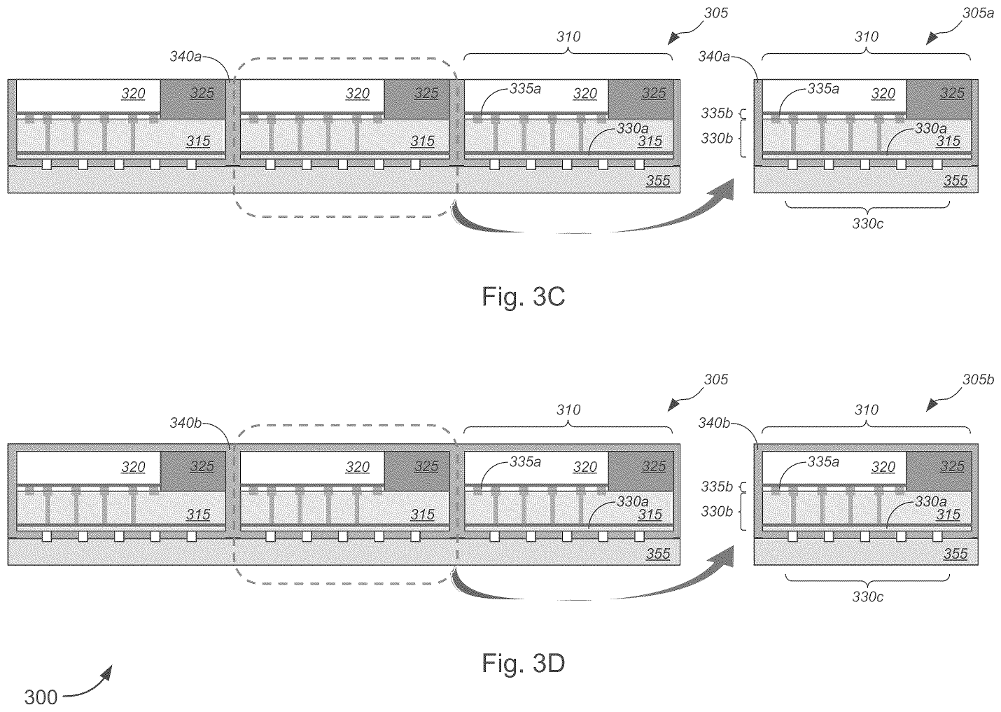

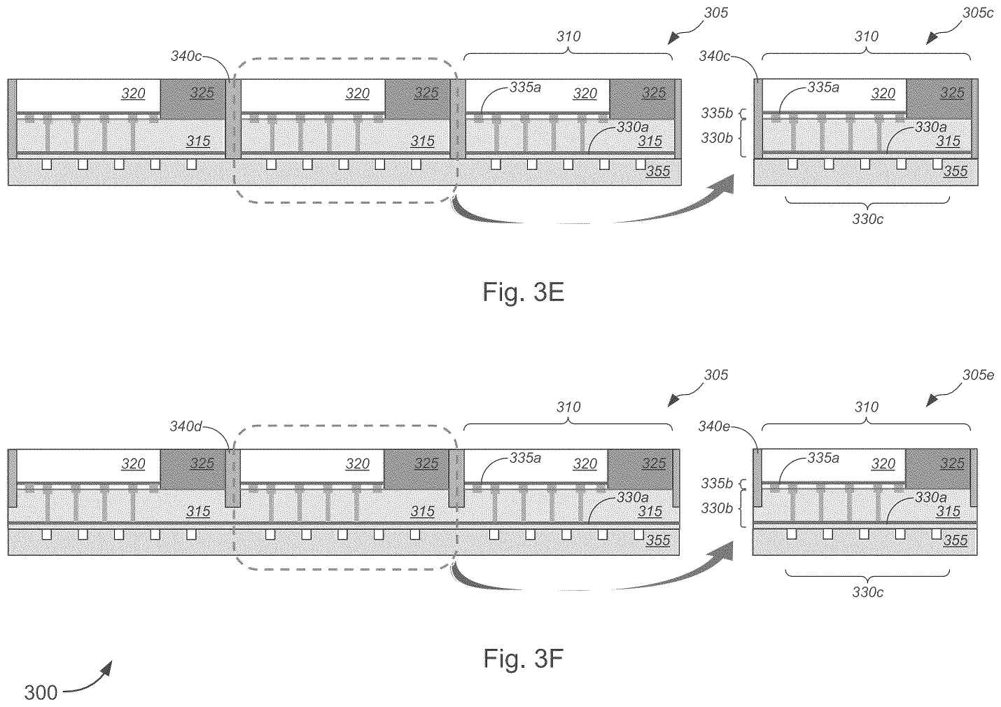

FIG. 3A-3F (collectively, “FIG. 3”) are schematic diagrams illustrating sectional or cutaway elevation views of a non-limiting set of examples 300 of forming composite structures, in the form of bonded stacks of different size semiconductor devices, with edge seals during implementation of edge seal for bonded stacks of different size semiconductor devices, in accordance with various embodiments.

FIG. 3 depicts an array 305 of composite structures 310, each including, but not limited to, a first semiconductor device 315, a second semiconductor device 320, a mold region 325, first active circuit 330a, associated one or more first interface components 330b, and a plurality of first protruding electrical contact terminals 330c for the first semiconductor device 315, second active circuit 335a and associated one or more second interface components 335b for the second semiconductor device 320, and sealant material 340a, 340b, 340c, or 340e (collectively, “sealant material 340” or “edge seal” or the like; as described below). FIG. 3 also depicts saw street or paths 350a (before dicing or cutting, as shown, e.g., in FIG. 3A, or the like) and 350b (after dicing or cutting, as shown, e.g., in FIG. 3B, or the like), tape 355 that may be used to protect exposed bottom surfaces during movement of the array of composite structures 310 or of subsequently separated semiconductor devices 305a, 305b, 305c, or 305e (corresponding to semiconductor devices 105a, 105b, 105c, or 105e, respectively, of FIGS. 1A, 1B, 1C, and 1E, to similar semiconductor devices 105g, 105h, 105i, or 105k, respectively, of FIGS. 1G, 1H, 1I, and 1K, to similar semiconductor devices 105m, 105n, 105o, or 105q, respectively, of FIGS. 1M, 1N, 1O, and 1Q, or to similar semiconductor devices 105s, 105t, 105u, or 105w, respectively, of FIGS. 1S, 1T, 1U, and 1W, or the like). Although not shown in FIG. 3, semiconductor devices 105d, 105j, 105p, and 105v of FIGS. 1D, 1J, 1P, and 1V, as well as semiconductor devices 105f, 1051, 105r, and 105x of FIGS. 1F, 1L, 1R, and 1X may be formed and subsequently diced or cut in a similar manner. As shown in FIGS. 3C-3F, the sealant material or edge seal 340 is applied along at least the side surfaces of each composite structure 310 that are exposed due to the dicing or cutting process.

In general, semiconductor devices 305, composite structures 310, first semiconductor device 315, second semiconductor device 320, mold region 325, first active circuit 330a, first interface components 330b, first protruding electrical contact terminals 330c, second active circuit 335a, second interface components 335b for the second semiconductor device 320, and sealant material 340 of FIG. 3 are similar, if not identical, to corresponding semiconductor devices 105, composite structures 110, first semiconductor device 115, second semiconductor device 120, mold region 125, first active circuit 130a, first interface components 130b, first protruding electrical contact terminals 130c, second active circuit 135a, second interface components 135b for the second semiconductor device 120, and sealant material 140, respectively, of FIG. 1, and the descriptions of these components of FIG. 1 similarly apply to the corresponding components of FIG. 3.

These and other functions of example 300 (and its components) are described in greater detail herein with respect to FIGS. 1, 2, 4, and 5.

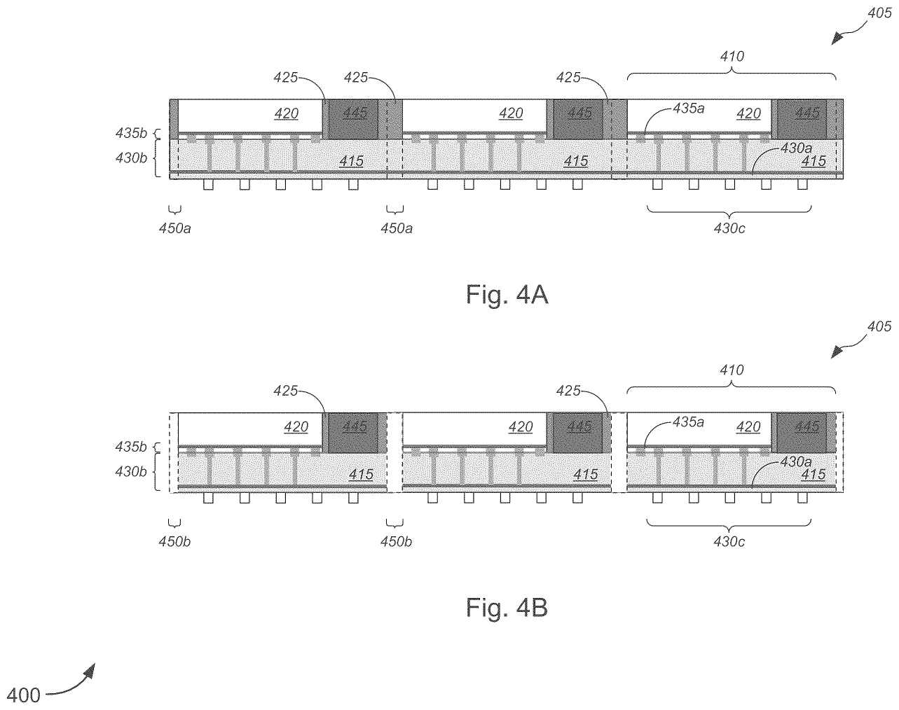

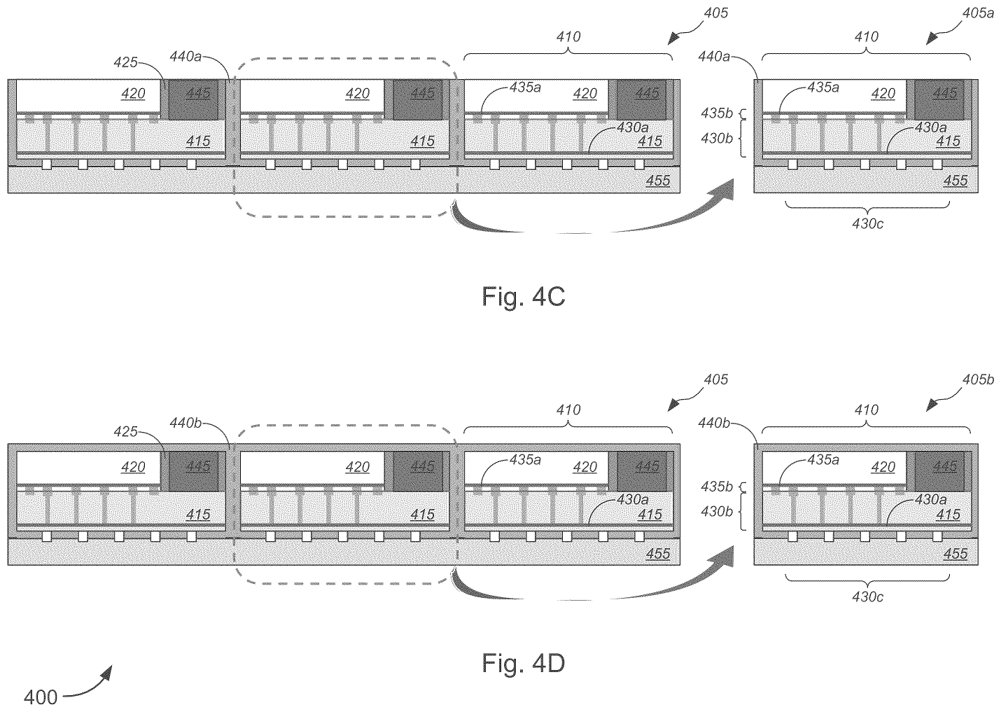

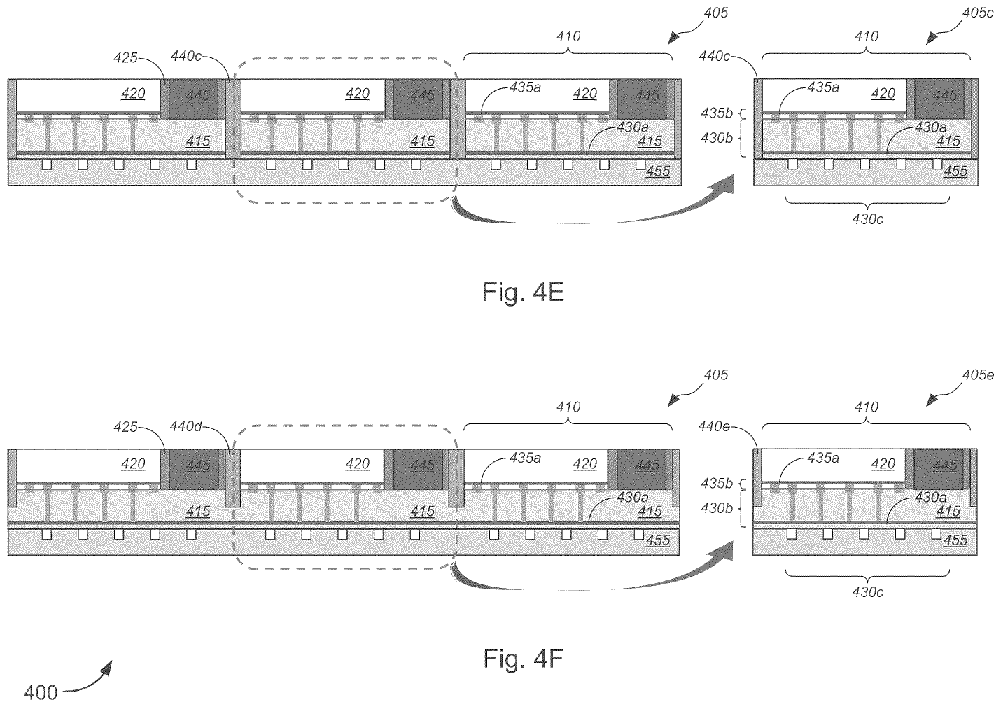

FIGS. 4A-4F (collectively, “FIG. 4”) are schematic diagrams illustrating sectional or cutaway elevation views of another non-limiting set of examples 400 of forming composite structures, in the form of bonded stacks of different size semiconductor devices, with edge seals during implementation of edge seal for bonded stacks of different size semiconductor devices, in accordance with various embodiments.

FIG. 4 depicts an array 405 of composite structures 410, each including, but not limited to, a first semiconductor device 415, a second semiconductor device 420, a mold region 425, first active circuit 430a, associated one or more first interface components 430b, and a plurality of first protruding electrical contact terminals 430c for the first semiconductor device 415, second active circuit 435a and associated one or more second interface components 435b for the second semiconductor device 420, sealant material 440a, 440b, 440c, or 440e (collectively, “sealant material 440” or “edge seal” or the like; as described below), and at least one dummy die 445 (similar to at least one dummy die 245 of FIG. 2, or the like). FIG. 4 also depicts saw street or paths 450a (before dicing or cutting, as shown, e.g., in FIG. 4A, or the like) and 450b (after dicing or cutting, as shown, e.g., in FIG. 4B, or the like), tape 455 that may be used to protect exposed bottom surfaces during movement of the array of composite structures 410 or of subsequently separated semiconductor devices 405a, 405b, 405c, or 405e (corresponding to semiconductor devices 105a, 105b, 105c, or 105e, respectively, of FIGS. 1A, 1B, 1C, and 1E, to similar semiconductor devices 105g, 105h, 105i, or 105k, respectively, of FIGS. 1G, 1H, 1I, and 1K, to similar semiconductor devices 105m, 105n, 105o, or 105q, respectively, of FIGS. 1M, 1N, 1O, and 1Q, or to similar semiconductor devices 105s, 105t, 105u, or 105w, respectively, of FIGS. 1S, 1T, 1U, and 1W, or the like). Although not shown in FIG. 4, semiconductor devices 105d, 105j, 105p, and 105v of FIGS. 1D, 1J, 1P, and 1V, as well as semiconductor devices 105f, 1051, 105r, and 105x of FIGS. 1F, 1L, 1R, and 1X may be formed and subsequently diced or cut in a similar manner. As shown in FIGS. 4C-3F, the sealant material or edge seal 440 is applied along at least the side surfaces of each composite structure 410 that are exposed due to the dicing or cutting process.

In general, semiconductor devices 405, composite structures 410, first semiconductor device 415, second semiconductor device 420, mold region 425, first active circuit 430a, first interface components 430b, first protruding electrical contact terminals 430c, second active circuit 435a, second interface components 435b for the second semiconductor device 420, and sealant material 440 of FIG. 4 are similar, if not identical, to corresponding semiconductor devices 105, composite structures 110, first semiconductor device 115, second semiconductor device 120, mold region 125, first active circuit 130a, first interface components 130b, first protruding electrical contact terminals 130c, second active circuit 135a, second interface components 135b for the second semiconductor device 120, and sealant material 140, respectively, of FIG. 1, and the descriptions of these components of FIG. 1 similarly apply to the corresponding components of FIG. 4. The at least one dummy die 445 is similar, if not identical to the at least one dummy die 245 of FIG. 2, and descriptions of dummy die 445 similarly apply to dummy die 245.

These and other functions of example 400 (and its components) are described in greater detail herein with respect to FIGS. 1-3 and 5.

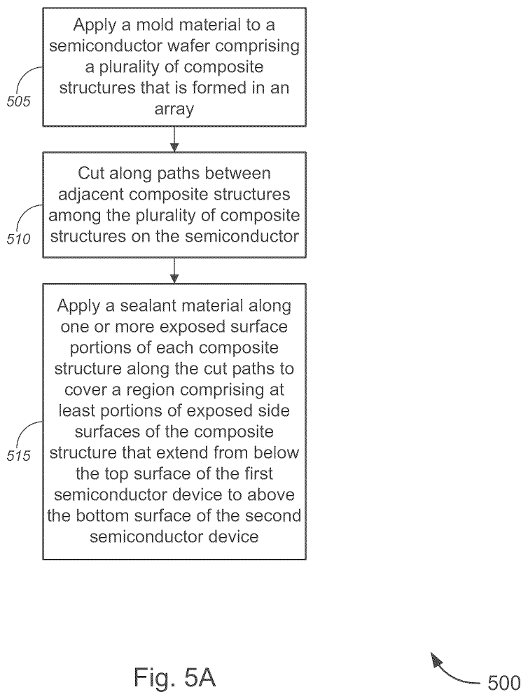

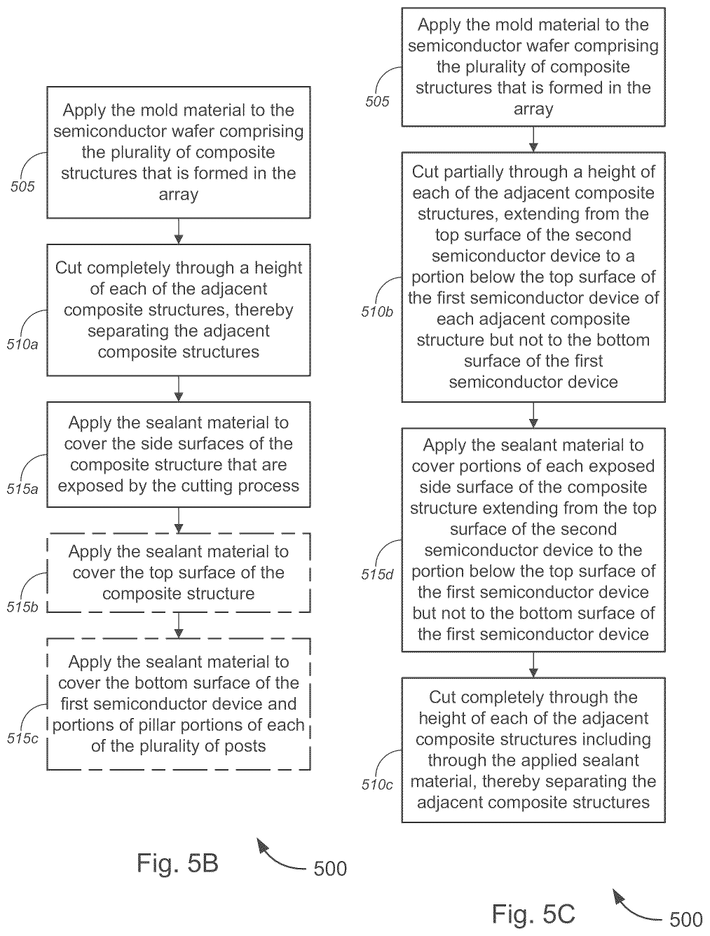

FIGS. 5A-5C (collectively, “FIG. 5”) are flow diagrams illustrating a method for implementing edge seal for bonded stacks of different size semiconductor devices, in accordance with various embodiments.

While the techniques and procedures are depicted and/or described in a certain order for purposes of illustration, it should be appreciated that certain procedures may be reordered and/or omitted within the scope of various embodiments. Moreover, while the method 500 illustrated by FIG. 5 can be implemented by or with (and, in some cases, are described below with respect to) the systems, examples, or embodiments 100, 100′, 200, 200′, 300, and 400 of FIGS. 1A-1H, 1I-1P, 2A-2D, 2E-2H, 3, and 4, respectively (or components thereof), such methods may also be implemented using any suitable hardware (or software) implementation for semiconductor processes. Similarly, while each of the systems, examples, or embodiments 100, 100′, 200, 200′, 300, and 400 of FIGS. 1A-1H, 1I-1P, 2A-2D, 2E-2H, 3, and 4, respectively (or components thereof), can operate according to the method 500 illustrated by FIG. 5, the systems, examples, or embodiments 100, 100′, 200, 200′, 300, and 400 of FIGS. 1A-1H, 1I-1P, 2A-2D, 2E-2H, 3, and 4 can each also operate according to other modes of operation and/or perform other suitable procedures.

In the non-limiting embodiment of FIG. 5A, method 500, at block 505, may comprise applying a mold material to a semiconductor wafer comprising a plurality of composite structures that is formed in an array. In some instances, each of the plurality of composite structures may include a composite structures such as shown and described above with respect to one of FIGS. 1A-1P, or the like. In some embodiments, each composite structure includes, without limitation, a first semiconductor device and a second semiconductor device. In some instances, the first semiconductor device includes, but is not limited to, a top surface, a bottom surface, side surfaces extending between the top surface and the bottom surface, and one or more first interface components extending at least from one or more portions of the top surface. In some cases, edges between the top surface and the side surfaces define a first lateral perimeter, the first lateral perimeter defining a first area. Similarly, the second semiconductor device includes, but is not limited to, a top surface, a bottom surface, side surfaces extending between the top surface and the bottom surface, and one or more second interface components extending at least from one or more portions of the bottom surface. In some cases, edges between the bottom surface and the side surfaces define a second lateral perimeter, the second lateral perimeter defining a second area, the second area being different in size than the first area. In some instances, the first and second semiconductor devices form a stacked configuration with the second semiconductor device being disposed on or over the first semiconductor device and with each of the one or more first interface components bonded with a corresponding one of the one or more second interface components. According to some embodiments, the mold material is applied to fill, for each composite structure, a region (“mold region”), other than a space occupied by the second semiconductor device, above the first area that extends from the top surface of the first semiconductor device to a top surface of the second semiconductor device and that extends from an interior edge of the first lateral perimeter to other interior edges of the first lateral perimeter.

At block 510, method 500 comprises cutting along paths (e.g., saw streets 350 and 450 of FIGS. 3 and 4, or the like) between adjacent composite structures among the plurality of composite structures on the semiconductor. Method 500 further comprises applying a sealant material along one or more exposed surface portions of each composite structure along the cut paths to cover a region comprising at least portions of exposed side surfaces of the composite structure that extend from below the top surface of the first semiconductor device to above the bottom surface of the second semiconductor device (block 515) (in some cases, to cover at least each interface portion between stacked semiconductor devices). In some instances, applying the sealant material is performed either after cutting along all paths has been completed or as cutting is being performed and before cutting along all paths has been completed. In some cases, the one or more exposed surface portions of each composite structure have surface features resulting from the cutting process. In some instances, the surface features comprise at least one of one or more cracks, one or more signs of chipping, one or more grooves, one or more uneven surface portions, or one or more portions characteristic of delamination of the second semiconductor device from the first semiconductor device, and/or the like. In some cases, the sealant material fills in and seals the at least one of the one or more cracks, the one or more signs of chipping, the one or more grooves, or the one or more portions characteristic of delamination, and/or the like.

FIGS. 5B and 5C depict alternative embodiments that further detail the general embodiments shown and described above with respect to FIG. 5A.

In some embodiments, in the case that the second semiconductor device is smaller than the first semiconductor device, the side surfaces of each composite structure are defined by one of: the side surfaces of the first semiconductor device and side surfaces of the mold region; or the side surfaces of the first semiconductor device, one or more of the side surfaces of the mold region, and one or more of the side surfaces of the second semiconductor device. According to some embodiments, the composite structure further comprises at least one dummy die that is disposed within and replaces at least one portion of the mold region. In such cases, the side surfaces of each composite structure are defined by one of: the side surfaces of the first semiconductor device and side surfaces of the mold region; the side surfaces of the first semiconductor device, one or more of the side surfaces of the mold region, and one or more of the side surfaces of the second semiconductor device; the side surfaces of the first semiconductor device, one or more of the side surfaces of the mold region, and one or more side surfaces of each of one or more of the at least one dummy die; or the side surfaces of the first semiconductor device, one or more of the side surfaces of the mold region, one or more of the side surfaces of the second semiconductor device, and one or more side surfaces of each of one or more of the at least one dummy die; and/or the like. In some instances, each dummy die is an inactive semiconductor structure comprising a material that has at least one of mechanical, thermal, or electrical properties that match corresponding at least one of mechanical, thermal, or electrical properties of at least one of the first semiconductor device or the second semiconductor device. In some instances, a bottom surface or one or more third interface components of each dummy die is configured to facilitate bonding with the top surface or the one or more first interface components of the first semiconductor device. In some cases, a top surface of the composite structure is defined by the top surface of the second semiconductor device, the top surface of each dummy die (if present), and a top surface of the mold region. In some instances, the first semiconductor device further comprises a plurality of protruding electrical contact terminals extending at least from one or more portions of the bottom surface of the first semiconductor device. Alternatively, the second semiconductor device may be larger than the first semiconductor device.

With reference to FIG. 5B, method 500 comprises applying the mold material to the semiconductor wafer comprising the plurality of composite structures that is formed in the array (block 505); cutting completely through a height of each of the adjacent composite structures, thereby separating the adjacent composite structures (block 510a); applying the sealant material to cover the side surfaces of the composite structure that are exposed by the cutting process (block 515a); applying the sealant material to cover the top surface of the composite structure (optional block 515b); and applying the sealant material to cover the bottom surface of the composite structure (including the bottom surface of the first semiconductor device and portions of pillar portions of each of the plurality of protruding electrical contact terminals) (optional block 515c). In some cases, the sealant material application processes (at blocks 515a, 515b, and/or 515c) can be performed either sequentially in any order (with the process at block 515a together with one or both optional processes at blocks 515b or 515c being implemented) or in one manufacturing process step to seal all applicable sides of the composite structure (i.e., 5 sides if only one of the optional processes of block 515b or 515c is implemented together with the process at block 515a, or all 6 sides if both optional processes at blocks 515b and 515c are implemented together with the process at block 515a).

Alternatively, referring to FIG. 5C, method 500 comprises applying the mold material to the semiconductor wafer comprising the plurality of composite structures that is formed in the array (block 505); cutting partially through a height of each of the adjacent composite structures, extending from the top surface of the second semiconductor device to a portion below the top surface of the first semiconductor device of each adjacent composite structure but not to the bottom surface of the first semiconductor device (block 510b); applying the sealant material to cover portions of each exposed side surface of the composite structure extending from the top surface of the second semiconductor device to the portion below the top surface of the first semiconductor device but not to the bottom surface of the first semiconductor device (block 515d); and cutting completely through the height of each of the adjacent composite structures including through the applied sealant material, thereby separating the adjacent composite structures (block 515e).

While particular features and aspects have been described with respect to some embodiments, one skilled in the art will recognize that numerous modifications are possible. For example, the methods and processes described herein may be implemented using hardware components, software components, and/or any combination thereof. Further, while various methods and processes described herein may be described with respect to particular structural and/or functional components for ease of description, methods provided by various embodiments are not limited to any particular structural and/or functional architecture but instead can be implemented on any suitable hardware, firmware and/or software configuration. Similarly, while particular functionality is ascribed to particular system components, unless the context dictates otherwise, this functionality need not be limited to such and can be distributed among various other system components in accordance with the several embodiments.

Moreover, while the procedures of the methods and processes described herein are described in a particular order for ease of description, unless the context dictates otherwise, various procedures may be reordered, added, and/or omitted in accordance with various embodiments. Moreover, the procedures described with respect to one method or process may be incorporated within other described methods or processes; likewise, system components described according to a particular structural architecture and/or with respect to one system may be organized in alternative structural architectures and/or incorporated within other described systems. Hence, while various embodiments are described with—or without—particular features for ease of description and to illustrate some aspects of those embodiments, the various components and/or features described herein with respect to a particular embodiment can be substituted, added and/or subtracted from among other described embodiments, unless the context dictates otherwise. Consequently, although several embodiments are described above, it will be appreciated that the invention is intended to cover all modifications and equivalents within the scope of the following claims.

What is claimed is:

1. A semiconductor device, comprising:
a composite structure, comprising:
a first semiconductor device, the first semiconductor device having a top surface, a bottom surface, side surfaces extending between the top surface and the bottom surface, and one or more first interface components extending at least from one or more portions of the top surface, wherein edges between the top surface and the side surfaces define a first lateral perimeter, the first lateral perimeter defining a first area; and
a second semiconductor device, the second semiconductor device having a top surface, a bottom surface, side surfaces extending between the top surface and the bottom surface, and one or more second interface components extending at least from one or more portions of the bottom surface, wherein edges between the bottom surface and the side surfaces define a second lateral perimeter, the second lateral perimeter defining a second area, the second area being different in size than the first area, the first and second semiconductor devices forming a stacked configuration with the second semiconductor device being disposed on or over the first semiconductor device and with each of the one or more first interface components bonded with a corresponding one of the one or more second interface components; and
a sealant material that is disposed along one or more surface portions of the composite structure to cover a region comprising at least portions of side surfaces of the composite structure that extend from below the top surface of the first semiconductor device to above the bottom surface of the second semiconductor device.

2. The semiconductor device of claim 1, wherein the composite structure is formed on a semiconductor wafer among a plurality of composite structures that is formed in an array on the semiconductor wafer, wherein the side surfaces of the composite structure have surface features after separation from each of one or more adjacent composite structures among the plurality of composite structures that are formed on the semiconductor wafer.

3. The semiconductor device of claim 2, wherein the surface features comprise at least one of one or more cracks, one or more signs of chipping, one or more grooves, or one or more portions characteristic of delamination of the second semiconductor device from the first semiconductor device, wherein the sealant material fills in and seals the at least one of the one or more cracks, the one or more signs of chipping, the one or more grooves, or the one or more portions characteristic of delamination.

4. The semiconductor device of claim 1, wherein the sealant material comprises at least one of adhesive, thermoset resin, thermal conductive adhesive, mold compound, epoxy, or silicon dioxide-based material.

5. The semiconductor device of claim 1, wherein the composite structure further comprises a mold region that fills in a region, other than a space occupied by the smaller of the first semiconductor device or the second semiconductor device, the region being either:
(i) above the first area that extends from the top surface of the first semiconductor device to the top surface of the second semiconductor device and that extends from an interior edge of the first lateral perimeter to other interior edges of the first lateral perimeter when the second area is smaller than the first area; or
(ii) below the second area that extends from the bottom surface of the first semiconductor device to the bottom surface of the second semiconductor device and that extends from an interior edge of the second lateral perimeter to other interior edges of the second lateral perimeter when the second area is larger than the first area.

6. The semiconductor device of claim 5, wherein the mold region comprises a first material comprising at least one of adhesive, thermoset resin, thermal conductive adhesive, mold compound, epoxy, silicon dioxide-based material, or a dielectric material.

7. The semiconductor device of claim 5, wherein the composite structure further comprises at least one dummy die that is disposed within and replaces at least one portion of the mold region.

8. The semiconductor device of claim 7, wherein each dummy die is an inactive semiconductor structure comprising a second material that has at least one of mechanical, thermal, or electrical properties that match corresponding at least one of mechanical, thermal, or electrical properties of at least one of the first semiconductor device or the second semiconductor device, wherein a bottom surface or one or more third interface components of each dummy die is configured to facilitate bonding with the top surface or the one or more first interface components of the first semiconductor device.

9. The semiconductor device of claim 8, wherein the second material comprises at least one of silicon, glass, copper, aluminum, or a conductive alloy.

10. The semiconductor device of claim 5, wherein:
the second area is smaller than the first area;
the first semiconductor device further comprises a plurality of protruding electrical contact terminals extending at least from one or more portions of the bottom surface of the first semiconductor device;
a top surface of the composite structure is defined by at least one of the top surface of the second semiconductor device or a top surface of the mold region;
the side surfaces of the composite structure are defined by one of:
the side surfaces of the first semiconductor device and side surfaces of the mold region; or
the side surfaces of the first semiconductor device, one or more of the side surfaces of the mold region, and one or more of the side surfaces of the second semiconductor device; and
the region of the composite structure that is covered by the sealant material comprises one of:
the side surfaces of the composite structure;
a combination of the top surface of the composite structure and the side surfaces of the composite structure;
a combination of the bottom surface of the first semiconductor device, portions of pillar portions of each of the plurality of protruding electrical contact terminals, and the side surfaces of the composite structure;
a combination of the top surface of the composite structure, the bottom surface of the first semiconductor device, the portions of pillar portions of each of the plurality of protruding electrical contact terminals, and the side surfaces of the composite structure;
portions of each side surface of the composite structure extending from the top surface of the second semiconductor device to a portion below the top surface of the first semiconductor device but not to the bottom surface of the first semiconductor device; or
a combination of the top surface of the composite structure and the portions of each side surface of the composite structure extending from the top surface of the second semiconductor device to a portion below the top surface of the first semiconductor device but not to the bottom surface of the first semiconductor device.

11. A method, comprising:
applying a mold material to a semiconductor wafer comprising a plurality of composite structures that is formed in an array, each composite structure comprising:
a first semiconductor device, the first semiconductor device having a top surface, a bottom surface, side surfaces extending between the top surface and the bottom surface, and one or more first interface components extending at least from one or more portions of the top surface, wherein edges between the top surface and the side surfaces define a first lateral perimeter, the first lateral perimeter defining a first area; and
a second semiconductor device, the second semiconductor device having a top surface, a bottom surface, side surfaces extending between the top surface and the bottom surface, and one or more second interface components extending at least from one or more portions of the bottom surface, wherein edges between the bottom surface and the side surfaces define a second lateral perimeter, the second lateral perimeter defining a second area, the second area being different in size than the first area, the first and second semiconductor devices forming a stacked configuration with the second semiconductor device being disposed on or over the first semiconductor device and with each of the one or more first interface components bonded with a corresponding one of the one or more second interface components;
wherein the mold material is applied to fill, for each composite structure, a region (“mold region”), other than a space occupied by the smaller of the first semiconductor device or the second semiconductor device, the mold region being either:
(i) above the first area that extends from the top surface of the first semiconductor device to the top surface of the second semiconductor device and that extends from an interior edge of the first lateral perimeter to other interior edges of the first lateral perimeter when the second area is smaller than the first area; or
(ii) below the second area that extends from the bottom surface of the first semiconductor device to the bottom surface of the second semiconductor device and that extends from an interior edge of the second lateral perimeter to other interior edges of the second lateral perimeter when the second area is larger than the first area;
cutting along paths between adjacent composite structures among the plurality of composite structures on the semiconductor; and
applying a sealant material along one or more exposed surface portions of each composite structure along the cut paths to cover a region comprising at least portions of exposed side surfaces of the composite structure that extend from below the top surface of the first semiconductor device to above the bottom surface of the second semiconductor device.

12. The method of claim 11, wherein applying the sealant material is performed either after cutting along all paths has been completed or as cutting is being performed and before cutting along all paths has been completed.

13. The method of claim 11, wherein:
cutting along the paths between adjacent composite structures among the plurality of composite structures on the semiconductor wafer comprises cutting completely through a height of each of the adjacent composite structures, thereby separating the adjacent composite structures;
the side surfaces of each composite structure are defined by one of:
side surfaces of the mold region and the side surfaces of the larger of the first semiconductor device or the second semiconductor device; or
one or more of the side surfaces of the mold region, the side surfaces of the larger of the first semiconductor device or the second semiconductor device, and one or more of the side surfaces of the smaller of the first semiconductor device or the second semiconductor device; and
applying the sealant material comprises applying the sealant material to cover the side surfaces of the composite structure that are exposed by the cutting process.

14. The method of claim 13, wherein the first semiconductor device further comprises a plurality of protruding electrical contact terminals extending at least from one or more portions of the bottom surface of the first semiconductor device, wherein a top surface of the composite structure is defined by the top surface of the second semiconductor device and a top surface of the mold region, wherein applying the sealant material further comprises applying the sealant material to cover at least one of:
the top surface of the composite structure; or
the bottom surface of the first semiconductor device and portions of pillar portions of each of the plurality of protruding electrical contact terminals.

15. The method of claim 11, wherein:
the second area is smaller than the first area;
the composite structure further comprises at least one dummy die that is disposed within and replaces at least one portion of the mold region; and
the side surfaces of each composite structure are defined by one of:
the side surfaces of the first semiconductor device and side surfaces of the mold region;
the side surfaces of the first semiconductor device, one or more of the side surfaces of the mold region, and one or more of the side surfaces of the second semiconductor device;
the side surfaces of the first semiconductor device, one or more of the side surfaces of the mold region, and one or more side surfaces of each of one or more of the at least one dummy die; or
the side surfaces of the first semiconductor device, one or more of the side surfaces of the mold region, one or more of the side surfaces of the second semiconductor device, and one or more side surfaces of each of one or more of the at least one dummy die.

16. The method of claim 15, wherein each dummy die is an inactive semiconductor structure comprising a material that has at least one of mechanical, thermal, or electrical properties that match corresponding at least one of mechanical, thermal, or electrical properties of at least one of the first semiconductor device or the second semiconductor device, wherein a bottom surface or one or more third interface components of each dummy die is configured to facilitate bonding with the top surface or the one or more first interface components of the first semiconductor device.

17. The method of claim 11, wherein:
cutting along the paths between adjacent composite structures among the plurality of composite structures on the semiconductor wafer comprises cutting partially through a height of each of the adjacent composite structures, extending from the top surface of the second semiconductor device to a portion below the top surface of the first semiconductor device of each adjacent composite structure but not to the bottom surface of the first semiconductor device;
applying the sealant material comprises applying the sealant material to cover portions of each exposed side surface of the composite structure extending from the top surface of the second semiconductor device to the portion below the top surface of the first semiconductor device but not to the bottom surface of the first semiconductor device; and
the method further comprises:
cutting completely through the height of each of the adjacent composite structures including through the applied sealant material, thereby separating the adjacent composite structures.

18. The method of claim 11, wherein the one or more exposed surface portions of each composite structure have surface features resulting from the cutting process, wherein the surface features comprise at least one of one or more cracks, one or more signs of chipping, one or more grooves, one or more uneven surface portions, or one or more portions characteristic of delamination of the second semiconductor device from the first semiconductor device, wherein the sealant material fills in and seals the at least one of the one or more cracks, the one or more signs of chipping, the one or more grooves, or the one or more portions characteristic of delamination.

19. A semiconductor device, comprising:
a composite structure, comprising:
a first semiconductor device;
a second semiconductor device that is smaller than the first semiconductor device and that is disposed on or over and bonded to the first semiconductor device;
at least one dummy die that is smaller than the first semiconductor device and that is disposed on or over and bonded to the first semiconductor device; and
a mold region that fills in a first region, other than a space occupied by the second semiconductor device and each of the at least one dummy die, that extends from a top surface of the first semiconductor device to a top surface of the second semiconductor device or a top surface of the at least one dummy die and that extends from an interior edge of a lateral perimeter of the first semiconductor device to other interior edges of the lateral perimeter of the first semiconductor device; and
a sealant material that is disposed along one or more surface portions of the composite structure to cover a second region comprising at least portions of side surfaces of the composite structure that extend from below the top surface of the first semiconductor device to above a bottom surface of the second semiconductor device.

20. The semiconductor device of claim 19, wherein:
the first semiconductor device further comprises a plurality of protruding electrical contact terminals extending at least from one or more portions of a bottom surface of the first semiconductor device;
a top surface of the composite structure is defined by at least one of the top surface of the second semiconductor device, a top surface of the at least one dummy die, or a top surface of the mold region;
side surfaces of the composite structure are defined by one of:
side surfaces of the first semiconductor device and side surfaces of the mold region;
the side surfaces of the first semiconductor device, one or more of the side surfaces of the mold region, and one or more side surfaces of the second semiconductor device;
the side surfaces of the first semiconductor device, one or more of the side surfaces of the mold region, and one or more side surfaces of each of one or more of the at least one dummy die; or
the side surfaces of the first semiconductor device, one or more of the side surfaces of the mold region, one or more side surfaces of the second semiconductor device, and one or more side surfaces of each of one or more of the at least one dummy die; and
the second region of the composite structure that is covered by the sealant material comprises one of:
the side surfaces of the composite structure;
a combination of the top surface of the composite structure and the side surfaces of the composite structure;
a combination of the bottom surface of the first semiconductor device, portions of pillar portions of each of the plurality of protruding electrical contact terminals, and the side surfaces of the composite structure;
a combination of the top surface of the composite structure, the bottom surface of the first semiconductor device, the portions of pillar portions of each of the plurality of protruding electrical contact terminals, and the side surfaces of the composite structure;
portions of each side surface of the composite structure extending from the top surface of the second semiconductor device to a portion below the top surface of the first semiconductor device but not to the bottom surface of the first semiconductor device; or
a combination of the top surface of the composite structure and the portions of each side surface of the composite structure extending from the top surface of the second semiconductor device to a portion below the top surface of the first semiconductor device but not to the bottom surface of the first semiconductor device.
